(19) United States
(12) Patent Application Publication
(10) Pub. No.: US 2013/0126472 A1
(43) Pub. Date: May 23, 2013

(54) SUBSTRATE WITH ADHESION PROMOTING LAYER, METHOD FOR PRODUCING MOLD, AND METHOD FOR PRODUCING MASTER MOLD

(71) Applicant: Kota Suzuki, Shinjuku-ku (JP)

(72) Inventor: Kota Suzuki, Shinjuku-ku (JP)

(73) Assignee: HOYA CORPORATION, Shinjuku-ku, Tokyo (JP)

(21) Appl. No.: 13/703,189

(22) PCT Filed: Jun. 10, 2011
(86) PCT No.: PCT/JP2011/063382

§ 371 Date: Feb. 4, 2013

(30) Foreign Application Priority Data
Jun. 11, 2010 (JP) 2010-133839

(51) Int. Cl. G03F 7/004

(52) U.S. Cl. CPC G03F 7/004
USPC 216/47; 430/270.1; 430/280.1

(57) ABSTRACT

Disclosed is a substrate with an adhesive auxiliary layer having an organic compound layer provided on a substrate, with an adhesive auxiliary layer to be interposed between the substrate and the organic compound layer wherein one molecule of a compound contained in the adhesive auxiliary layer includes an adsorption functional group and an adhesion promoting functional group, the adsorption functional group is composed of a modified silane group which is mainly bonded to the substrate, and the adhesion promoting functional group promotes and increases adhesion mainly to the organic compound layer.

### TECHNICAL FIELD

The present invention relates to a substrate with an adhesive auxiliary layer for forming a designed pattern on a substrate, a manufacturing method of a mold, and a manufacturing method of a master mold.

### BACKGROUND ART

Conventionally, in magnetic media used for hard disks and the like, methods have been used in which magnetic particles are miniaturized, the width of the magnetic head is minimized, and intervals between data tracks where information is recorded are narrowed, thereby increasing the recording density. On the other hand, the recording density of the magnetic media has been greatly increased, and magnetic influence between adjacent recording tracks or between recording bits has become measurable. Therefore, conventional methods have a limitation in increasing the recording density.

Recently, new magnetic media, called patterned media, have been proposed. These patterned media are aimed to achieve higher recording density by magnetically separating adjacent recording tracks or recording bits by means of a guard band formed of a groove or nonmagnetic material, reducing magnetic interference, and improving signal quality thereby.

As a technology for mass-manufacturing the patterned media, there is a well-known technology called an imprint method (or a nanoimprint method), which is a technique for creating a patterned medium by transferring projection and recess patterns included in a master mold (also referred to as a master) or a copy mold, which has been formed by copying the master mold as an original mold once or a plurality of times, to a transfer target object (herein, a magnetic medium).

In the imprint method described herein, to mass-produce the medium by transferring patterns onto a final transfer target object (product), a master mold is not generally used. As stated above, what is used instead is a secondary mold that has been formed by transferring tiny projection and recess patterns of the master mold to another transfer target object by means of a nanoimprint method, or a tertiary mold that has been formed by transferring the tiny patterns of the secondary mold to another transfer target object, or a higher-order copy mold.

Furthermore, for example, to actually manufacture a large number of above-mentioned patterned media, a plurality of imprinting apparatuses arranged in parallel are to be operated. Therefore, for the plurality of imprinting apparatuses, it is necessary to produce a plurality of copy molds on which the same predetermined tiny projection and recess patterns have been formed.

Herein, in the nanoimprint method, to smoothly release the mold from a transfer target object (i.e., a substrate for copy mold production), the surface of the mold (i.e., the surface of the projection and recess pattern) is beforehand coated with a mold release agent composition to form a demolding layer.

On the other hand, the surface of the above-mentioned substrate for copy mold production (i.e., the surface to which the projection and recess pattern is to be transferred) is beforehand coated with an adhesive auxiliary layer composed of an adhesive auxiliary agent composition. After that, a nanoimprint resist (e.g., UV-curable resin) is applied onto the adhesive auxiliary layer by a spin-coating method or an ink-jet method, thereby forming a resist layer.

Thus, by making the adhesive strength between the resist layer and the substrate for copy mold production greater than the adhesive strength between the resist layer and the mold, the resist layer on which projection and recess patterns of the mold have been transferred (i.e., resist pattern) can be formed on the substrate for copy mold production.

By doing so, it is possible to release the mold from the substrate for copy mold production smoothly with low demolding pressure.

As a result, it is possible to suppress and reduce damage (such as removal or disappearance) to the transferred resist pattern, damage to the pattern on the mold, contamination of the mold (such as transfer of removed resist pattern) due to a demolding failure or an adhesion failure; or it is also possible to suppress and reduce damage to the mold or the imprinting apparatus.

However, if adhesive strength between the substrate and the resist layer is not sufficient, in the process of releasing a mold from a substrate for copy mold production, a part of the resist layer on which projection and recess patterns have been transferred could possibly be removed or disappear. Even if the pattern is not removed, the resist pattern could collapse, or deformation including waviness could possibly occur to the resist pattern.

Furthermore, there is a well-known technology for producing a master mold, which is a master of the above-mentioned copy mold, by which a predetermined projection and recess pattern is etched directly on a substrate by a photolithographic technique to produce a mold (e.g., refer to PTL 1). For example, a resist layer is formed on a hard mask layer for etching formed on the main surface of a quartz substrate (or it is simply formed on the main surface of a quartz substrate) and then a pattern is drawn by irradiating an energy beam (e.g., electron beam) onto the resist layer. After that, the drawn resist layer is developed to form a predetermined resist pattern, and finally, the predetermined projection and recess pattern is formed on the substrate, producing a master mold.

However, in the same manner as a copy mold, if adhesive strength between the hard mask layer (or a quartz substrate) and the resist layer is not sufficient, a part of a resist pattern could possibly be removed or disappear in the process of development. Or, the resist pattern could collapse, or deformation including swell could possibly occur to the resist pattern.

Thus, if an abnormality occurs to the resist pattern in the process of manufacturing a master mold or a copy mold, defect (deficiency) or deformation occurs to the predetermined projection and recess pattern that is to be formed on a finally-produced master mold or copy mold, or the accuracy of the pattern (accuracy of the shape and size) decreases (those are also collectively referred to as pattern failures).

Furthermore, a pattern failure occurring to a master mold is transferred to a copy mold. In addition to the pattern defect transferred from the original mold, a new pattern failure could occur at the time of the production of a copy mold; then defects of projection and recess patterns of copy molds sequentially produced further increase, resulting in the decreased accuracy of the pattern.

a pattern failure generated in a master mold is transferred and copied to a copy mold. Further, in addition to the pattern failure that exists in an original mold and transferred and copied to the copy mold, a pattern failure is newly generated during fabricating the copy mold, thus further increasing a defect of the projection and recess pattern of the copy mold which is copied one after another, and further deteriorating an accuracy of the pattern.

Moreover, quality and accuracy of the final products (e.g., magnetic media) produced by the imprint method will deteriorate, or problems with a production yield could possibly occur.

Herein, in order to increase adhesive strength between the substrate and the resist layer, PTL 2 describes the technique which, by interposing an adhesion layer between the substrate and the resist layer by means of the surface treatment using a silane coupling agent, can effectively prevent collapse, removal, and deformation of the pattern even by the development process by means of high-pressure injection.

Furthermore, in order to increase adhesive strength between the substrate and the photosensitive resist, PTL 3 describes the technique for forming an adhesion layer on the surface of the substrate by using HMDS (hexamethyldisilazane) as a constituent material.

Moreover, PTL 4 describes the technique which can prevent disappearance and deformation of the pattern and produce a substrate with a designed tiny metallic thin-film pattern by using a light-cured layer of light curable resin composed of benzophenone as a nanoimprint adhesive excellent in bonding together a metallic thin film and a thermoplastic polymer and sequentially providing the above nanoimprint adhesive and the thermoplastic polymer film layer on the metallic thin film.

### CITATION LIST

### Patent Literature

PTL 1: Japanese Unexamined Patent Application Publication No. 2008-310944
PTL 2: Japanese Unexamined Patent Application Publication No. 2001-281878
PTL 3: Japanese Unexamined Patent Application Publication No. 2008-064812
PTL 4: Japanese Unexamined Patent Application Publication No. 2009-073809

### Non Patent Literature

NPL 1: Latest technology for perpendicular magnetic recording (CMC Publishing, CO., LTD., published in 2007)

### SUMMARY OF INVENTION

### Technical Problem

Recently, request for miniaturization of patterns has been more and more increased. Specifically, to take the growth of recording density of magnetic media as an example, the area of a pattern (one bit) to achieve recording density of one terabit per square inch is 625 square nm (NPL 1). Assuming that the interval between bits is 25 nm, the track pitch is also 25 nm. If a 10-nm groove is individually formed between adjacent bits and between adjacent tracks, tiny, 15-nm square patterns are to be formed. Furthermore, surface recording density of magnetic media has been increased by 60% to 100% on an annual basis, and higher recording density is also expected.

Therefore, even if there is provided a combination of a resist layer and a substrate sufficiently adhering to each other by using an adhesive auxiliary layer composed of a silane coupling agent or an HMDS, there is a possibility that decreased adhesive strength due to the significant reduction of the area of contact between the above-mentioned resist pattern and the foundation layer (substrate) could cause pattern failures such as removal, collapse, and deformation of the resist pattern, resulting in limiting the accuracy and quality of final products or production yield.

Furthermore, if light curable resin described in PTL 4 is used as an adhesive, the adhesive does not function as an adhesion layer unless it is irradiated with ultraviolet light. Accordingly, a process of the ultraviolet irradiation so as to form an adhesion layer is additionally necessary prior to the formation of the resist pattern, which could possibly increase production costs.

In the light of the above circumstances, an objective of the present invention is to provide a substrate with an adhesive auxiliary layer having sufficient adhesive strength and enabling the accurate formation of patterns, a manufacturing method of a mold, and a manufacturing method of a master mold.

### Solution to Problem

A first aspect in accordance with the present invention provides a substrate with an adhesive auxiliary layer having an organic compound layer provided on a substrate, with an adhesive auxiliary layer to be interposed between the substrate and the organic compound layer,

wherein one molecule of a compound contained in the adhesive auxiliary layer includes an adsorption functional group and an adhesion promoting functional group,

the adsorption functional group is composed of a modified silane group which is mainly bonded to the substrate, and

the adhesion promoting functional group promotes and increases adhesion mainly to the organic compound layer.

A second aspect in accordance with the present invention provides the substrate with an adhesive auxiliary layer described in the first aspect, wherein

the organic compound layer is a resist layer, and

a photoradical reaction is induced between the adhesion promoting functional group and the resist layer.

A third aspect in accordance with the present invention provides the substrate with an adhesive auxiliary layer described in the first aspect, wherein

the adhesion promoting functional group is a functional group in which when a chemical agent that is a source of the organic compound layer is applied to the adhesive auxiliary layer, a contact angle between the adhesive auxiliary layer and the chemical agent is 30 degrees or less.

A fourth aspect in accordance with the present invention provides the substrate with an adhesive auxiliary layer described in the first or second aspect, wherein the adhesion promoting functional group is a mercapto group.

A fifth aspect in accordance with the present invention provides the substrate with an adhesive auxiliary layer described in the first or third aspect, wherein the adhesion promoting functional group is a methacryl group or an epoxy group.

A sixth aspect in accordance with the present invention provides the substrate with an adhesive auxiliary layer described in any one of the first to fifth aspects, wherein the adhesion promoting functional group is provided on at least one terminal of a molecular chain.

A seventh aspect in accordance with the present invention provides the substrate with an adhesive auxiliary layer described in any one of the first to sixth aspects, wherein the modified silane group is provided on at least one terminal of a molecular chain.

An eighth aspect in accordance with the present invention provides the substrate with an adhesive auxiliary layer described in any one of the first to seventh aspects, wherein the modified silane group is an alkoxysilane group.

A ninth aspect in accordance with the present invention provides the substrate with an adhesive auxiliary layer described in the eighth aspect, wherein the alkoxysilane group is a trimethoxy silane group.

A tenth aspect in accordance with the present invention provides the substrate with an adhesive auxiliary layer described in any one of the first to ninth aspects, wherein the organic compound layer is a resist layer, and the resist layer is composed of light curable resin.

An eleventh aspect in accordance with the present invention provides the substrate with an adhesive auxiliary layer described in any one of the first to ninth aspects, wherein the organic compound layer is a resist layer, and the resist layer is composed of a resist for electron-beam lithography exposure having no substantial sensitivity to an ultraviolet band.

A twelfth aspect in accordance with the present invention provides a substrate with an adhesive auxiliary layer where an adhesive auxiliary layer is provided on a substrate and a resist layer is to be provided via the adhesive auxiliary layer,

wherein

a trimethoxy silane group is provided on one terminal of a molecular chain in one molecule of a compound contained in the adhesive auxiliary layer, and

a mercapto group, a methacryl group, or an epoxy group is provided on the other terminal.

A thirteenth aspect in accordance with the present invention provides a manufacturing method of a mold wherein a another copy mold is manufactured from an imprint mold provided with an projection and recess pattern that corresponds to a designed pattern, the method comprising:

forming a hard mask layer on a substrate for producing the another copy mold, an adhesive auxiliary layer on the hard mask layer, and an imprint resist layer for pattern formation (hereafter, also referred to as a resist layer) on the adhesive auxiliary layer;

transferring a pattern provided on the mold onto the resist layer by imprinting; and

separating the mold from the resist layer and then applying etching to the hard mask layer by using the resist layer with a transferred designed pattern as a mask, wherein

an adsorption functional group and an adhesion promoting functional group are included in one molecule of a compound contained in the adhesive auxiliary layer,

the adsorption functional group made of a modified silane group is mainly bonded to the substrate by baking the adhesive auxiliary layer during formation of this layer, and

the adhesion promoting functional group promotes and increases adhesion mainly to the resist layer.

A fourteenth aspect in accordance with the present invention is characterized in that

in the invention described in the thirteenth aspect,

in the step of transferring an projection and recess pattern provided on the mold onto the resist layer by an optical imprint method,

a photoradical reaction is induced between the resist layer and the adhesion promoting functional group by an irradiation light used in the optical imprint method.

A fifteenth aspect in accordance with the present invention provides a manufacturing method of a master mold for imprint, comprising:

forming a hard mask layer on a substrate, an adhesive auxiliary layer on the hard mask layer, and an electron-beam lithography exposure resist layer for pattern formation (also referred to as an electron-beam resist layer) on the adhesive auxiliary layer;

irradiating the substrate having the hard mask layer, the adhesive auxiliary layer, and the electron-beam resist layer sequentially formed thereon, with a light by using a light irradiation apparatus;

drawing and exposing a designed pattern on the electron-beam resist layer by an electron-beam lithography (exposure) system, and the electron-beam resist layer is then developed, to thereby form a predetermined resist pattern; and

applying etching to the hard mask layer by using the electron-beam resist layer with a designed pattern formed thereon (resist pattern) as a mask,

wherein

an adsorption functional group and an adhesion promoting functional group are included in one molecule of a compound contained in the adhesive auxiliary layer,

the adsorption functional group made of a modified silane group is mainly bonded to the substrate by baking the adhesive auxiliary layer during formation of this layer, and

the adhesion promoting functional group promotes and increases adhesion mainly to the resist layer.

A sixteenth aspect in accordance with the present invention is characterized in that

in the invention described in the fifteenth aspect,

a photoradical reaction is induced between the electron beam resist layer and the adhesion promoting functional group by the light irradiation at least before developing of the electron-beam resist layer.

### Advantageous Effects of Invention

According to the present invention, it is possible to provide a substrate with an adhesive auxiliary layer having sufficient adhesive strength and enabling the accurate formation of patterns, a manufacturing method of a mold, and a manufacturing method of a master mold.

### BRIEF DESCRIPTION OF DRAWINGS

FIG. 1 is a cross-sectional schematic view for explaining the process of manufacturing a copy mold by using a substrate with an adhesive auxiliary layer according to this embodiment.

FIG. 2 shows the results of adhesive strength of the substrates with an adhesive auxiliary layer obtained in the examples and comparative examples.

FIG. 3 shows the results of surface free energy of the substrates with an adhesive auxiliary layer obtained in the examples and comparative examples.

FIG. 4 shows the observation results of the substrates with an adhesive auxiliary layer, obtained in the examples and comparative examples, by using an atomic force microscope (AFM).

FIG. 5 shows the results of surface roughness of the substrates with an adhesive auxiliary layer obtained in the examples and comparative examples.

FIG. 6 is a schematic view showing a method of obtaining adhesive strength of the substrates with an adhesive auxiliary layer obtained in the examples and comparative examples.

### DESCRIPTION OF EMBODIMENTS

The inventors of the present invention studied various kinds of adhesive auxiliary layers which are interposed between a substrate and an organic compound layer, such as a resist, and which have sufficient adhesive strength to both the substrate and the organic compound layer and aid the adhesive strength of the organic compound layer to the substrate, thereby accurately forming a pattern. In the course of the study, the inventors of the present invention first focused a silane coupling agent which provides sufficient adhesive strength for substrates.

Then, the inventors of the present invention conceived of providing an adhesion promoting functional group, which can promote and increase adhesive strength mainly to the organic compound layer, in addition to the modified silane group in one molecule of the compound constituting the silane coupling agent.

This composition enables one molecule to increase the adhesive strength between a substrate and a resist layer. Also, it is possible to set the thickness of the adhesive auxiliary layer to nearly the length of one molecule (i.e., nano order).

Furthermore, it was found possible to increase pattern accuracy by increasing adhesive strength, or decreasing surface roughness while maintaining a certain level of adhesive strength according to the type of the adhesion promoting functional group.

### Embodiment 1

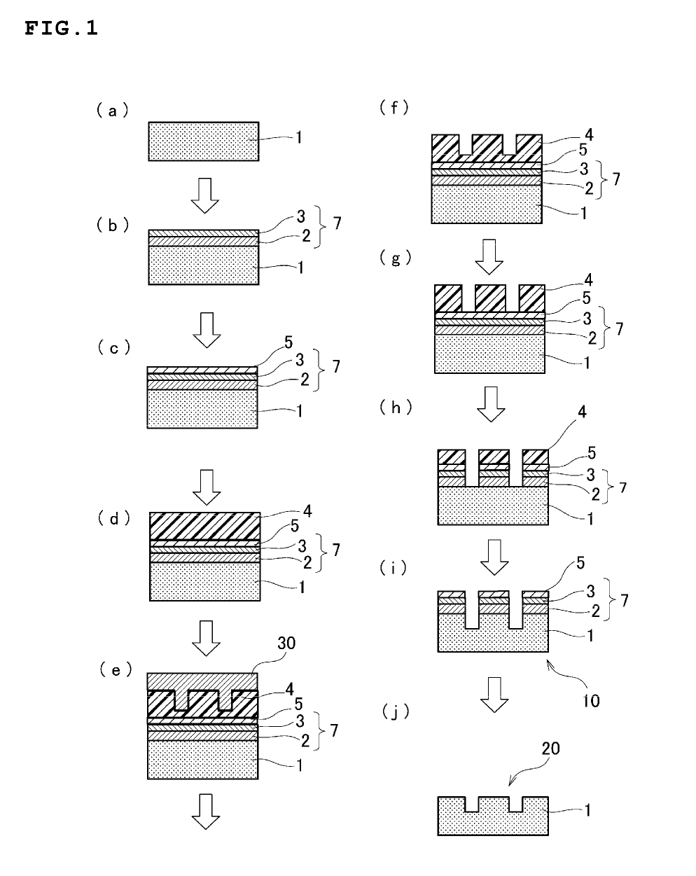

Hereafter, an embodiment of the present invention will be described with reference to FIG. 1 which is a cross-sectional schematic view for explaining the process of manufacturing an imprint mold, specifically a manufacturing method of a copy mold.

(Outline of the Mold Production Process)

In this embodiment, a blank is used to produce a copy mold. There is one general blank wherein a hard mask layer 7 has been formed on a substrate 1 as shown in FIG. 1(b).

Subsequently, an adhesive auxiliary layer 5 according to this embodiment is formed on the hard mask layer 7, and then a resist layer 4 is further provided on the adhesive auxiliary layer 5.

In the future, an original mold 30 on which a designed pattern has been formed is pressed onto the resist layer 4, thereby transferring the pattern onto a blank for copy mold production. In the course of the pattern transfer, it is possible to promote and increase adhesive strength between the hard mask layer 7 and the resist layer 4 by the above-mentioned adhesive auxiliary layer.

As a result, it is possible to accurately form a resist pattern on the resist layer 4 by preventing deficiency or deformation of the resist pattern in the imprint method (process), specifically at the time of the demolding. Accordingly, it is possible to reproduce a designed pattern onto the hard mask layer 7 and eventually on the substrate 1.

The above-mentioned substrate 1, hard mask layer 7, adhesive auxiliary layer 5 and the resist layer 4 will be described in detail below.

(Preparation of a Substrate)

First, a substrate 1 is prepared to produce a copy mold 20 (FIG. 1(a)).

Any substrate is usable if the substrate 1 can be used as a copy mold 20. For example, a silicon wafer, or a glass substrate, such as a quartz substrate, may be used. As described later, a hard mask layer 7 made of material having a high etching selectivity to substrate material may be formed on the substrate.

Furthermore, the shape of the substrate 1 may be a discotic shape, or may be a rectangular shape, polygonal shape, or semicircular shape.

In this embodiment, explanation will be given by use of a discotic (shape of wafer) quartz substrate 1. Hereafter, the quartz substrate 1 is also simply referred to as a substrate 1.

(Formation of a Hard Mask Layer)

Next, as shown in FIG. 1(b), the quartz substrate 1 is loaded into a sputtering apparatus. Subsequently, in this embodiment, a target made of an alloy of tantalum (Ta) and hafnium (Hf) is sputtered with an argon gas, forming a conductive layer 2 made of a tantalum-hafnium alloy; and then, a target made of chrome (Cr) is sputtered with an argon gas and a nitrogen gas, forming a chromium nitride layer 3.

Thus, as shown in FIG. 1(b), a hard mask layer 7 comprising a conductive layer 2 made of a tantalum-hafnium alloy as being a lower layer and a chromium nitride layer 3 as being an upper layer is formed on the quartz substrate 1.

Furthermore, the “hard mask layer” in this embodiment may be composed of a single layer or a plurality of layers. Moreover, when etching the substrate 1, it is necessary to reliably protect the portion in which a projected portion (projection) that corresponds to the projection and recess of a resist pattern to be formed later is to be created. That is, any material may be used if an etching selectivity to the substrate 1 is sufficient with respect to the etching of the substrate 1. Further, the hard mask layer is preferably conductive. This is because by electrically grounding the hard mask layer 7, it is possible to prevent static electricity that could possibly occur as well as defect (electrostatic collapse) resulting from the static electricity during the imprinting process (at the time of transfer), specifically at the time of the demolding.

Thus, a substrate with a hard mask layer 7 formed thereon is referred to as a blank for copy mold production (or simply called a blank) in this embodiment.

Moreover, the blank may be irradiated with vacuum ultraviolet (VUV) light as necessary to remove static electricity.

(Formation of an Adhesive Auxiliary Layer on a Blank)

In this embodiment, after the hard mask layer 7 on the blank has been cleaned and baked, the hard mask layer 7 is coated with an adhesive auxiliary agent, as shown in FIG. 1(c), thereby providing an adhesive auxiliary layer 5.

In so doing, after the adhesive auxiliary agent has been applied, baking treatment is implemented to induce dehydration synthesis in the adhesive auxiliary agent. The baking temperature is preferably 100° C. or higher. The reason is that dehydration synthesis of the modified silane group occurs on the hard mask layer 7 and the modified silane group binds with the hard mask layer 7, which makes it possible to securely bind the adhesive auxiliary layer 5 with the hard mask layer 7.

In this embodiment, the baking treatment is important. The meaning of the baking in this embodiment and the difference between “adsorption” and “bonding” of the modified silane group with respect to the hard mask layer 7 will be described in detail later after the adsorption functional group and the adhesion promoting functional group are explained.

(Outline of the Compound Composition of the Adhesive Auxiliary Layer)

First, one molecule of the compound included in the adhesive auxiliary layer 5 according to this embodiment includes an adsorption functional group made of a modified silane group which is mainly bonded to the hard mask layer 7 and an adhesion promoting functional group that promotes and increases adhesion mainly to the resist layer 4.

(Adsorption Functional Group)

It is sufficient if the adsorption functional group is a modified silane group. The modified silane group is preferably an alkoxysilane group. Specifically, trimethoxy silane, triethoxysilane, dimethoxysilane, diethoxysilane, methoxysilane, and ethoxysilane are available. In terms of high bonding strength with the hard mask layer 7 and high adhesive strength, trimethoxy silane is preferable. Hereafter, the adsorption functional group is also referred to as a modified silane group. Furthermore, the modified silane group includes the state where the modified silane group is bonded to a substrate.

Furthermore, it is preferable that the modified silane group be provided on at least one terminal of the molecular chain. This is because if a modified silane group is located on a terminal, like trimethoxy silane, the modified silane group can include a large number of methoxy groups that contribute to the bonding.

Moreover, it was explained that the adsorption functional group is bonded to the hard mask layer 7. Specifically, it is considered that dehydration synthesis of water or a hydroxyl group present on the hard mask layer 7 and the modified silane group occurs, forming a strong covalent bonding between the adsorption functional group and the hard mask layer 7.

(Adhesion Promoting Functional Group)

Next, detailed description will be given about the adhesion promoting functional group which is actively used for the resist layer 4 formed on the adhesive auxiliary layer 5. As stated above, the adhesion promoting functional group is located in a molecular chain in a molecule of the compound constituting the adhesive auxiliary layer 5.

Herein, promotion and increase of the adhesive strength of the adhesive auxiliary layer to the resist layer 4 is due to two actions.

The first action is that the adhesion promoting functional group itself chemically reacts with the resist layer 4, thereby increasing the adhesive strength between the adhesive auxiliary layer 5 and the resist layer 4.

The second action is that by making the adhesion promoting functional group similar to the composition of the resist layer 4, that is, by making the adhesive auxiliary layer 5 easily fit in with the resist layer 4, the adhesive strength between the adhesive auxiliary layer 5 and the resist layer 4 is increased.

First, the first action will be explained. Ultraviolet exposure is used for curing a resist layer when transferring a projection and recess pattern provided on an original mold 30 to a copy mold fabricating substrate (i.e., to a copy mold) which is a transfer receiving substrate. Simultaneously, the first action uses this ultraviolet exposure for functional manifestation (i.e., promotion and increase of adhesive strength) of the adhesive auxiliary layer 5 interposed between the hard mask layer 7 and the resist layer 4. In this case, a mercapto group (also referred to as a thiol group) is preferably used as an adhesion promoting functional group.

If a mercapto group is contained in a compound constituting an adhesive auxiliary layer 5, it is possible to initiate an ene-thiol reaction, which is a photoradical reaction, between a resist layer, which is an organic compound layer, and a mercapto group by the ultraviolet irradiation. Therefore, it is not necessary to provide an additional process to increase adhesive strength.

Furthermore, to specifically describe a compound that includes the mercapto group, it is the compound having the following chemical formula.

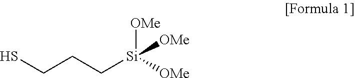

Other than the mercapto group, any functional group can be used as an adhesive auxiliary agent according to this embodiment if it increases adhesive strength to a resist layer 4 as the result of the ultraviolet irradiation.

Next, the second action will be explained. This action makes an adhesion promoting functional group similar to the composition of the resist layer 4 so as to make the adhesive auxiliary layer 5 fit in with the resist layer 4.

For example, the method of “fitting in” is to set the adhesion promoting functional group to a predetermined one and make it difficult to repel the resist layer 4 due to the adhesive auxiliary layer 5.

That is, it is preferable to set a functional group so that the contact angle between the adhesive auxiliary layer 5 and a solution droplet of the composition constituting the resist layer 4 is 30 degrees or less when the droplet is dropped at the time of the application of the resist layer 4 on the adhesive auxiliary layer 5.

For example, a methacryl group is a functional group that contributes to setting the above contact angle to be 30 degrees or less.

To specifically describe the methacryl group compound, it is the compound having the following chemical formula.

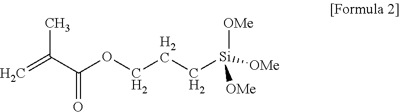

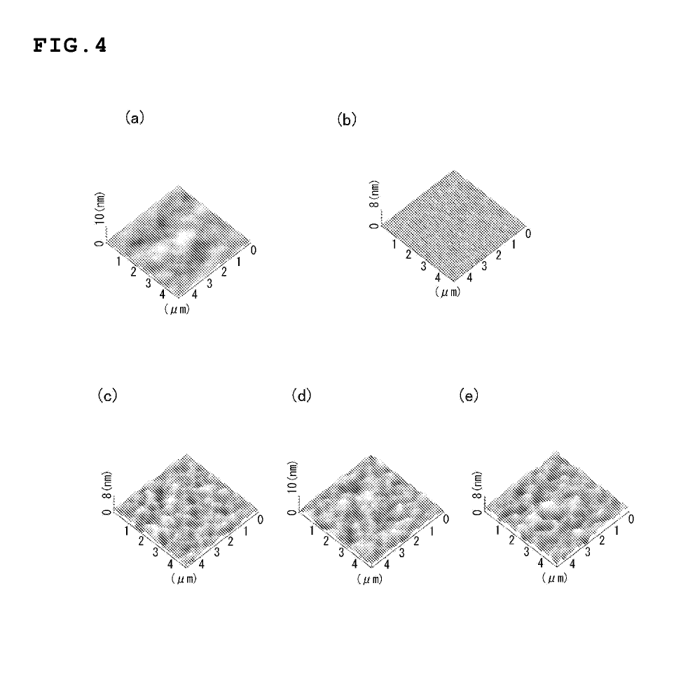

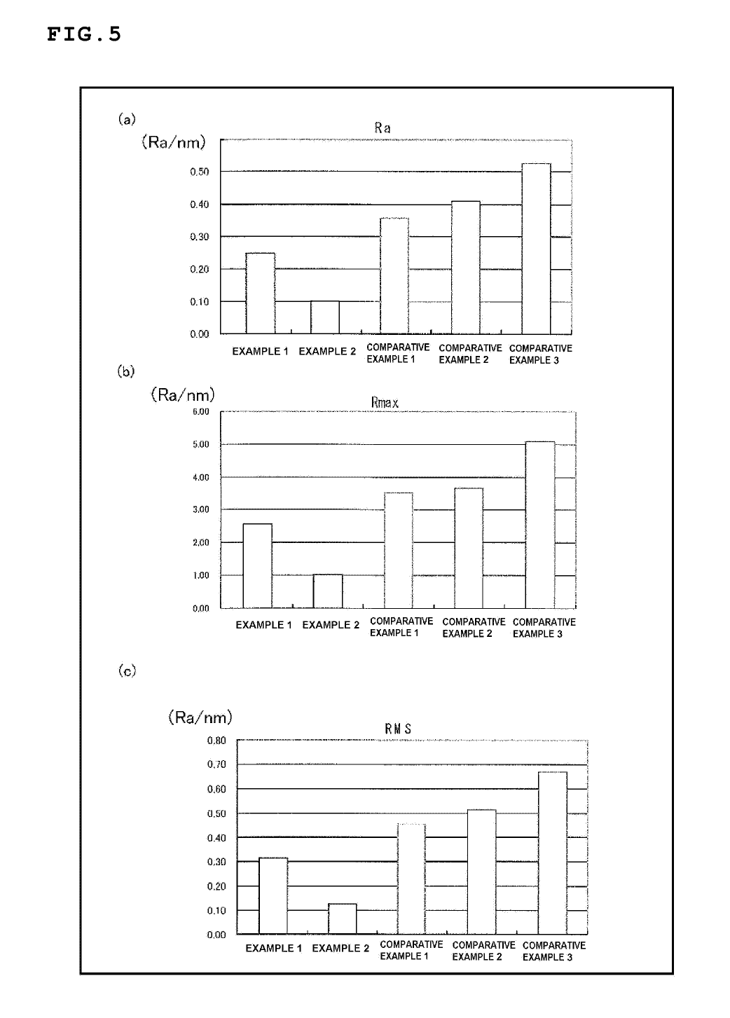

By using an adhesion promoting functional group as a methacryl group, it is possible to make the adhesive auxiliary layer 5 and the resist layer 4 fit well and also smooth the surface of the adhesive auxiliary layer 5 (FIG. 4 and FIG. 5). This is described in detail in examples later.

Furthermore, explanation will be given about a method of making at least a part of the composition of the resist layer 4 similar to the adhesive auxiliary layer 5.

Since a resist containing epoxy resin is frequently used for the resist layer 4, an adhesion promoting functional group is also preferably used as an epoxy group.

Furthermore, to specifically describe the epoxy group compound, it is the compound having the following chemical formula.

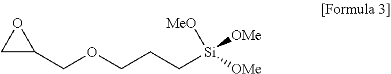

The adhesion promoting functional group described herein is preferably provided on at least one terminal of the molecular chain in one molecule of the compound constituting the adhesive auxiliary layer 5. If the adhesion promoting functional group is provided on one terminal in the same way as the modified silane group, it is possible to anchor one terminal to the hard mask layer 7 and the other terminal to the resist layer 4. As a result, it is possible to significantly promote and increase adhesive strength between the hard mask layer 7 and the resist layer 4.

Furthermore, the number of adhesion promoting functional groups provided in the compound constituting the adhesive auxiliary layer 5 may be a single number or a plural number. It is considered that if the appropriate number of adhesion promoting functional groups are provided, adhesive strength between the hard mask layer 7 and the adhesive auxiliary layer 5 can be increased.

Moreover, if one molecule includes an adsorption functional group and an adhesion promoting functional group, it is possible to bind a substrate with a resist layer by one molecule. And, the thickness of the adhesive auxiliary layer 5 can be set to nearly the length of one molecule.

Furthermore, although the molecular chain of the molecule may be a branched-chain or a straight chain, the molecular chain is preferably a straight chain in terms of increase in adhesive strength by thickening the inside of the adhesive auxiliary layer 5. Herein, one molecule consists of one molecular chain, and one molecular chain includes a main chain and a side chain branched from the main chain.

Moreover, although it is preferable that the major component of the adhesive auxiliary agent be a compound including the above-mentioned molecule, a conventional substance that can be added to the adhesive auxiliary agent may be contained. Obviously, the adhesive auxiliary agent may be composed of only the above compound.

As stated above, the adhesive auxiliary layer 5 is located between the hard mask layer 7 and the resist layer 4 and binds those layers with the adhesive auxiliary layer 5 interposed. From a different view point, on the stage before the resist layer 4 is formed, the modified silane group in the adhesive auxiliary layer 5 has already been turned mainly to the hard mask layer 7, while the adhesion promoting functional group is turned mainly to the direction in which the resist layer 4 is to be formed (i.e., main surface side). This means that the direction of the molecular chain in the adhesive auxiliary layer 5 is almost constant. This is achieved by baking treatment which is implemented after the adhesive auxiliary agent has been applied. Hereafter, the mechanism of making the direction of the molecular chain almost constant will be explained.

First, an adhesive auxiliary agent is applied on a hard mask layer 7. At this time, in the molecular chain of one molecule of the adhesive auxiliary agent, a modified silane group adsorbs onto the hard mask layer 7; and when the adhesion promoting functional group is a mercapto group, the mercapto group could also possibly adsorb onto the hard mask layer 7. That is, at this point in time, the direction of the molecular chain of the adhesive auxiliary agent on the hard mask layer 7 is not constant. As described, the state before baking in which the adsorption functional group and the adhesion promoting functional group of the adhesive auxiliary agent are bonded to the hard mask layer 7 itself or water thereon is referred to as “adsorption” in this embodiment.

However, when baking is conducted after the application of the adhesive auxiliary agent, dehydration synthesis of the modified silane group of the adhesive auxiliary agent and the hydroxyl group on the surface of the hard mask layer occurs. As a result, of all functional groups included in the adhesive auxiliary agent, the modified silane group is selectively bonded to the hard mask layer 7 by means of covalent bonding. Thus, the state after baking in which the adsorption functional group of the adhesive auxiliary agent is bonded to the hard mask layer 7 by covalent bonding is referred to as “bonding” in this embodiment.

On the contrary, when compared with a modified silane group, a mercapto group, which is an adhesion promoting functional group, has poor bonding strength with a hydroxyl group on the surface of the hard mask layer. Consequently, the mercapto group is turned to the direction away from the hard mask layer 7 (i.e., the direction of the main surface on which a resist layer 4 is formed). Obviously, it is not clear whether or not all of the molecular chains have the above direction. However, since dehydration synthesis of the modified silane group occurs, most of the molecular chains are considered to have the above direction to the extent of exhibiting sufficient adhesive strength.

(Formation of a Resist Layer)

Next, as shown in FIG. 1(d), an optical imprint resist is applied to the adhesive auxiliary layer 5, thereby forming a resist layer 4. As stated above, on the stage of the application of the resist, an adhesion promoting functional group mainly exists in a portion of the adhesive auxiliary layer 5 that comes in contact with the resist.

The resist layer 4 used in this embodiment may be any organic compound layer. As stated above, it is sufficient if the resist layer can chemically react with an adhesion promoting functional group or fit in well with an adhesion promoting functional group.

With regard to the imprint method in this embodiment, a method of transferring a pattern on the original mold 30 onto a resist layer 4 by means of an optical imprint method will be described. With this, the use of an optical imprint resist as an organic compound layer will be described.

By thus using an optical imprint resist, when a mercapto group is used as an adhesion promoting functional group as stated above, the use of exposure at the time of the pattern transfer initiates the occurrence of the ene-thiol reaction, which is a photoradical reaction, and makes it possible to increase adhesive strength between the hard mask layer 7 and the resist layer 4.

The thickness of the resist layer 4 at this time is preferably the thickness that allows the resist on the portion that functions as a mask to remain until the completion of the etching of the chromium nitride layer 3.

For example, the optical imprint resist is the one made of light curable resin, specifically ultraviolet curable resin; however, any light curable resin is sufficient if it is appropriate for the etching process to be conducted later.

The above is the process of forming an adhesive auxiliary layer 5 on a blank and subsequently forming a resist layer 4 on top of it.

Hereafter, description will be given about the process of producing a mold by means of the optical imprint method by using a substrate 1 with the adhesive auxiliary layer 5.

(Imprinting Process)

Hereafter, description will be given about the imprinting process in which a pattern is transferred by the optical imprint method onto a transfer receiving substrate (i.e., a substrate for copy mold production) that has been created such that an adhesive auxiliary layer 5 is formed on the above-mentioned blank and a resist layer 4 is subsequently formed on top of it.

First, as shown in FIG. 1(e), a predetermined projection and recess pattern is formed on a substrate for copy mold production having a resist layer 4 formed as stated above, an original mold 30 with a demolding layer is then pressed onto the substrate for copy mold production, and the resist layer 4 fills up the projection and recess pattern of the mold.

The resist layer 4 that fills up the projection and recess pattern of the mold is then irradiated with ultraviolet light, thereby hardening the resist layer 4 with the transferred pattern. At this time, ultraviolet light is generally irradiated onto the backside of the original mold 30; however, when the substrate 1 is a transmissive substrate, the light may be irradiated onto the backside of the substrate 1. After that, the original mold 30 and the substrate 1 for mold production which is a transfer target substrate are removed from each other.

Furthermore, to prevent misalignment of the pattern between the original mold 30 and the substrate 1 for mold production, an alignment pattern (alignment mark) may be additionally provided on the original mold 30 and the substrate 1 for mold production according to the alignment mechanism, and the substrate 1 for mold production and the original mold 30 can be aligned prior to the imprinting process.

(First Etching)

Next, the substrate 1 for copy mold production with the resist pattern is loaded into the dry-etching apparatus. Subsequently, residual film remaining at the bottom of the recessed portion of the resist layer 4 having a projection and recess pattern and the adhesive auxiliary layer 5 are removed in the first etching process (also referred to as ashing) that uses plasma of gas such as oxygen, fluorine gas, or argon gas, thereby exposing the hard mask layer 7.

As shown in FIG. 1(g), a resist pattern that corresponds to a desired pattern is thus formed. Moreover, in the projected portion (i.e., the portion in which the residual film has been removed and the hard mask layer 7 is exposed) of the resist layer 4 with the projection and recess pattern, a groove is to be eventually formed on the substrate 1.

(Second Etching)

Next, the substrate 1 for copy mold production where a resist pattern has been formed on the hard mask layer 7 is loaded into the dry-etching apparatus. Then, the second etching process is conducted in which the exposed hard mask layer 7 is removed by etching in an atmosphere that includes chlorine gas and oxygen gas. The endpoint of etching at that time is determined by a catoptric system endpoint detector, predetermined over-etching is then conducted, and finally etching is finished.

Thus, as shown in FIG. 1(h), a resist layer 4 with a pattern, an adhesive auxiliary layer 5, and a hard mask layer 7 are formed.

(Third Etching)

Subsequently, after the gas used for the second etching has been vacuum exhausted, the third etching of the quartz substrate 1 is conducted in the same dry-etching apparatus by use of a fluorine gas.

In this process, the quartz substrate 1 is etched with the hard mask layer 7 used as a mask, and a groove that corresponds to the pattern is formed on the substrate 1 as shown in FIG. 1(i). Before or after the process, the resist layer 4 is removed by an alkaline solution or an acidic solution.

Fluorine gases used herein are as follows: CₓF_{y} (e.g., CF₄, C₂F₆, C₃F₈), CHF₃, mixed gas of those, or gases that contain a noble gas (He, Ar, Xe, etc.) as an added gas.

Thus, as shown in FIG. 1(i), the projection and recess shape that corresponds to the pattern is formed on the quartz substrate 1. Thus, a mold 10 with the remaining hard mask layer is produced.

(Fourth Etching)

Next, with regard to the above-mentioned mold 10 with the remaining hard mask layer, the following process is conducted by the same method as the first etching: the excess resist layer 4 that remains on the mold 10 with the remaining hard mask layer, the adhesive auxiliary layer 5, and the hard mask layer 7 are removed by a dry etching gas, thereby producing a copy mold 20 (FIG. 1(j)).

In the above first to fourth etching processes, any one etching process may use wet etching and the other etching processes may use dry etching; or all etching processes may use wet etching or dry etching. Furthermore, when the pattern size is in the micron order, wet etching may be introduced according to the size of the pattern; for example, wet etching is conducted in the micron order and dry etching is conducted in the nano order.

Although the first to fourth etching processes are performed in this embodiment, an additional etching process may be added between the first and second etching processes according to a substance constituting the substrate 1 for copy mold production.

(Completion of the Copy Mold)

After the excess resist layer 4, the adhesive auxiliary layer 5, and the hard mask layer 7 have been removed through the above-mentioned processes, if necessary, cleaning of the substrate 1 is conducted. Thus, the copy mold 20 as shown in FIG. 1(j) is completed.

The following advantageous effects can be obtained in this embodiment.

First, by using a compound that includes a modified silane group as a compound constituting an adhesive auxiliary layer 5, it is possible to provide sufficient adhesive strength for the hard mask layer 7.

Then, by using a compound that includes an adhesion promoting functional group along with the modified silane group, it is possible to provide sufficient adhesive strength for the resist layer 4.

To promote the adhesive strength, when configuration (composition) of the adhesion promoting functional group itself chemically reacts with the resist layer 4 due to the ene-thiol reaction, it is possible to utilize ultraviolet irradiation which is used for hardening the resist layer to which the projection and recess pattern of the original mold 30 has been transferred.

That is, it is not necessary to provide an additional ultraviolet irradiation process so as to increase adhesive strength (to make the adhesive auxiliary layer 5 function).

As a result, according to the adhesive auxiliary layer of this embodiment, sufficient adhesive strength can be obtained, a designed pattern can be accurately formed, that is, transferred and reproduced.

The technological concept of this embodiment can be applied to the cases where an organic compound layer, such as a resist, is to be bonded to another substance. Specifically, this embodiment can be favorably applied to the copy mold produced by use of the imprinting technique. Similarly, this embodiment can be favorably applied to the patterned media manufactured by use of the imprinting technique.

### Embodiment 2

Hereafter, description will be given about a process of manufacturing a nanoimprint master mold, which is a master for producing a copy mold described in embodiment 1.

(Outline of the Master Mold Production Process)

In embodiment 2, a substrate for mold production is used to produce a master mold in the same manner as embodiment 1. A general substrate for mold production is a substrate 1 with a hard mask layer 7 formed thereon as shown in FIG. 1(b) described in detail in embodiment 1. Hereafter, in embodiment 2, the same reference sign plus “′” are assigned to the same configuration of embodiment 1.

An adhesive auxiliary layer 5′ according to this embodiment is formed on the hard mask layer 7′, then an electron-beam resist layer 4′ made of an electron-beam lithography resist is further formed on the adhesive auxiliary layer 5′.

Next, the substrate 1′ on which the adhesive auxiliary layer 5′ and the electron-beam resist layer 4′ have been formed is irradiated with ultraviolet light.

Next, the created resist layer 4′ is irradiated with an electron beam spot, for example, thereby drawing a designed pattern.

After that, the electron-beam resist layer 4′ on which a designed pattern has been drawn by means of an electron beam is developed using a predetermined developer.

Finally, removal of the adhesive auxiliary layer 5′ and residue including the tailing of the electron-beam resist pattern (first etching), etching of the hard mask layer 7′ (second etching), etching of the substrate 1′ (third etching), and removal of the excess hard mask layer 7′ and the electron-beam resist layer 4′ formed thereon (fourth etching) are sequentially conducted, and finally a nanoimprint master mold having a projection and recess pattern that corresponds to a designed pattern on the surface of the substrate is completed.

Next, the above-mentioned substrate 1′, hard mask layer 7′, adhesive auxiliary layer 5′, and the electron-beam resist layer 4′ will be described in detail below.

(Preparation of a Substrate)

First, a substrate 1′ is prepared to produce a master mold 20′ (FIG. 1(a)).

Any material may be used for the substrate 1′ if it can be used as a master mold 20′. To take an example, silicon wafers, or glass substrates such as quartz substrates may be used.

To limit to the optical nanoimprint substrates, since light is irradiated to harden the resist layer 4′, the master mold needs to be transmissive with respect to the irradiation light.

Furthermore, the shape of the substrate 1′ may be a discotic shape, or may be a rectangular shape, polygonal shape, or semicircular shape. However, in the light of the nanoimprint method used for the master mold, the shape is preferably the same as the transfer target object or a similar figure that is larger than the transfer target object. Furthermore, the substrate 1′ may be constructed such that the substantial pattern forming area has a mesa structure.

In this embodiment, explanation will be given by use of a discotic (shape of a wafer) quartz substrate 1′. Hereafter, the quartz substrate 1′ is also simply referred to as a substrate 1′.

(Formation of a Hard Mask Layer)

Next, the formation of the hard mask layer 7′ will be described; however, it is the same as that in embodiment 1.

However, the hard mask layer is preferably conductive. By electrically grounding the hard mask layer 7′, it is possible to prevent charge-up when an electron-beam resist layer 4′ is drawn by an electron beam. Furthermore, it is possible to prevent static electricity that could possibly occur in the nanoimprinting process (at the time of the transfer), specifically at the time of the demolding, and defects (electrostatic collapse) resulting from the static electricity.

Later, if an electron-beam resist layer 4′ having a sufficiently high etching selectivity to a substrate 1′ is used, the hard mask layer 7′ does not need to be formed.

(Formation of an Adhesive Auxiliary Layer, and the Outline of the Compound Composition of the Adhesive Auxiliary Layer)

The formation of the adhesive auxiliary layer 5′ is also the same as that in embodiment 1.

Furthermore, composition of the compound constituting the adhesive auxiliary layer 5′ is the same as the configuration in embodiment 1. That is, one molecule of the compound (i.e., adhesive auxiliary agent) contained in the adhesive auxiliary layer 5′ according to this embodiment includes an adsorption functional group composed of a modified silane group that binds mainly with the hard mask layer 7′ and an adhesion promoting functional group that promotes and increases adhesion mainly to the electron-beam resist layer 4′.

Furthermore, the chemical composition and the manifestation of chemical functions of the adsorption functional group and the adhesion promoting functional group are in accordance with embodiment 1.

(Formation of an Electron-Beam Resist Layer)

Next, as shown in FIG. 1(d), an electron-beam lithography resist constituting an electron-beam resist layer 4′ is applied, by a spin-coating method or the like, to the substrate 1′ with the adhesive auxiliary layer 5′ and then baked, thereby forming an electron-beam resist layer 4′.

Any electron-beam resist layer 4′ may be used in this embodiment if it chemically reacts with an adhesion promoting functional group in a molecule of the compound constituting the adhesive auxiliary layer 5′ and fits in well with an adhesion promoting functional group.

Furthermore, the electron-beam lithography resist constituting an electron-beam resist layer 4′ used in this embodiment substantially has no sensitivity to ultraviolet light (no absorption of ultraviolet light) but has necessary and sufficient sensitivity to electron beams.

Herein, “substantially has no sensitivity to ultraviolet light” means that the resist is not sensitized even when irradiated with ultraviolet light. Furthermore, it means that even if the resist has sensitivity to ultraviolet light, the sensitivity is as low as the level at which a designed pattern can be obtained if lithography (exposure) by electron beams and subsequent development are conducted after the ultraviolet irradiation. When conducting lithography (exposure) by electron beams as in this embodiment, in order to form a designed pattern on the electron-beam resist layer by the electron-beam lithographic technique, a resist substantially having no sensitivity to ultraviolet light is used.

As stated above, when using a mercapto group as an adhesion promoting functional group, ultraviolet irradiation initiates the ene-thiol reaction which is a photoradical reaction, thereby promoting and increasing adhesive strength between the adhesive auxiliary layer 5′ and the electron-beam resist layer 4′. As a result, it is possible to promote and increase adhesive strength between the hard mask layer 7′ (or a quartz substrate 1′) and the electron-beam resist layer 4′.

Therefore, if an electron-beam resist layer 4′ formed on the adhesive auxiliary layer 5′ is transmissive with respect to ultraviolet light, by the irradiation of ultraviolet light after the formation of the electron-beam resist layer 4′, it is possible to promote and increase adhesive strength between the adhesive auxiliary layer 5′ and the electron-beam resist layer 4′. On the other hand, in the pattern formation, the electron-beam resist layer 4′ is not affected by the ultraviolet irradiation at all.

Herein, the thickness of the electron-beam resist layer 4′ is preferably the thickness that allows the resist on the portion (the convex portion of the resist pattern) that functions as a mask to sufficiently remain until the completion of the etching of the hard mask layer 7′(or a quartz substrate 1′). Furthermore, the thickness is preferably determined by taking into account a ratio between the size and height (i.e., aspect ratio) of the pattern to be formed so as to prevent collapse of the pattern resulting from capillarity during the drying process (generally, spin dry) which is the final treatment in the development process.

(Ultraviolet Irradiation Process)

As stated above, an adhesive auxiliary layer 5′ is formed on a substrate 1′, an electron-beam resist layer 4′ is subsequently formed thereon, and then, ultraviolet light is irradiated at least onto the substantial pattern forming area.

This manifests the function of the adhesive auxiliary layer 5′, thereby promoting and increasing adhesive strength between the adhesive auxiliary layer 5′ and the electron-beam resist layer 4′, that is, between the hard mask layer 7′ and the electron-beam resist layer 4′.

Furthermore, ultraviolet light is generally irradiated onto the electron-beam resist layer 4′ formed on the substrate 1′; however, when the substrate 1′ that includes a hard mask layer 7′ is transmissive or translucent, ultraviolet light may be irradiated onto the backside of the substrate 1′.

(Electron-Beam Lithography)

Next, the electron-beam resist layer 4′ is irradiated with an electron beam spot, for example, thereby drawing a designed pattern.

(Development)

Next, the electron-beam resist layer 4′ on which a designed pattern has been drawn by means of an electron beam is developed using a predetermined developer.

Specifically, the development enables the promotion and increase of the adhesive strength, which depends on the function of the adhesive auxiliary layer 5′, between the hard mask layer 7 and the resist layer 4′.

That is, by preventing the removal, disappearance, or deformation of the resist pattern that could possibly occur during the development process, it is possible to accurately form an electron-beam resist pattern. Accordingly, it is also possible to form a designed pattern on the hard mask layer 7′, finally on the substrate 1′.

(First Etching)

Next, the substrate 1′ with the electron-beam resist pattern formed thereon is loaded into the dry-etching apparatus. Then, the residual tailing present at the bottom of the recessed portion of the resist layer 4′ with the projection and recess pattern thereon and the adhesive auxiliary layer 5′ are removed in the first etching process (also referred to as descum) that uses plasma of gas, such as oxygen, fluorine gas, or argon, thereby exposing the hard mask layer 7′ that corresponds to the recessed portion of the resist layer 4′.

Thus, as shown in FIG. 1(g), an electron-beam resist pattern that corresponds to the designed pattern is formed. Further, a groove is finally formed at a part where a residue is removed, such as a skirting residue in the recessed portion of the resist layer 4′ on which the projection and recess pattern is formed, thereby exposing the hard mask 7′.

(Second to Fourth Etching)

Next, the substrate 1′ on which the resist pattern has been formed and a part of the hard mask layer 7′ is exposed is loaded into the dry-etching apparatus.

Then, second to fourth etching processes are conducted in accordance with embodiment 1.

(Completion of a Master Mold)

After the fourth etching process has been finished, if necessary, cleaning of the substrate 1 is conducted. Thus, the master mold 20′ as shown in FIG. 1(j) is completed.

The following advantageous effects can be obtained in this embodiment.

First, by using a compound including a modified silane group and an adhesion promoting functional group as a compound constituting an adhesive auxiliary layer 5′, it is possible to provide sufficient adhesive strength between the resist layer 4′ and the hard mask layer 7′ (or a substrate 1′).

In a case of a structure (composition) that a chemical reaction is induced between the adhesion promoting functional group and the resist layer 4 by the ene-thiol reaction, the adhesive auxiliary layer 5′ needs to be irradiated with a ultraviolet light after the resist layer 4′ is formed on the adhesive auxiliary layer 5′, to promote and improve the above-mentioned adhesive strength. This is enabled by using the resist layer 4′ as an electron-beam resist layer composed of an electron-beam resist which is neither absorbed in the ultraviolet wavelength band nor having a substantial sensitivity to the ultraviolet wavelength band.

As stated above, according to the adhesive auxiliary layer of this embodiment, it is possible to obtain sufficient adhesive strength and accurately form a designed pattern, that is, accurately produce a master mold.

The technological concept of this embodiment can be applied to the cases where an organic compound layer, such as a resist layer, is bonded to another substance. Specifically, this embodiment can be favorably applied to the copy mold produced by use of the nanoimprinting technique.

Similarly, this embodiment can be favorably applied to photomasks produced by use of the electron-beam lithographic technique.

Moreover, the “substrate” in the present invention may be any substrate if an adhesive auxiliary layer can be formed on the main surface thereof. Accordingly a so-called substrate itself and a substrate with a hard mask layer provided thereon are included.

Furthermore, the resist in this embodiment may be any resist if the resist is sensitive when exposed to an energy beam. Specifically, any resist may be used if it requires development using a developer and is sensitive to the ultraviolet light, X ray, electron beam, ion beam, electrically-charged particle beam, or proton beam. Similarly, according to the type of the resist to be used, an apparatus for irradiating ultraviolet light, X rays, electron beams, ion beams, electrically-charged particle beams, or proton beams may be used for exposing the resist.

### EXAMPLES

Next, examples will be shown to give specific description of the present invention. Obviously, this invention is not intended to be limited to the following examples.

### Example 1

As a substrate 1 for producing a copy mold 20 according to this example, a wafer (outer diameter 150 mm, thickness 0.7 mm) made of synthetic quartz was used (FIG. 1(a)). This quartz wafer (substrate 1) was loaded into the sputtering apparatus.

Then, a target made of an alloy of tantalum (Ta) and Hafnium (Hf) (the atom ratio of Ta to Hf=80:20) was sputtered with an argon gas, thereby forming a 7-nm thick conductive layer 2 made of a tantalum-hafnium alloy on the substrate that was used in the example.

Next, a chrome target was sputtered with a mixed gas of argon and nitrogen, thereby forming a 2.5-nm thick chromium nitride layer 3 (FIG. 1(b)).

A hard mask layer 7 composed of the conductive layer 2 and the chromium nitride layer 3 thus formed on the substrate 1 was exposed to vacuum ultraviolet (VUV) for two minutes. The substrate was coated with an adhesive auxiliary agent (Z6062 made by Dow Corning) that includes a modified silane group and a mercapto group by a spin coat technique. The number of revolutions at the time of application was 3000 rpm, and rotation was conducted for 30 seconds (FIG. 1(c)). After that, baking was conducted at 100° C. for one minute, and then a resist (PAKO1 made by Toyo Gosei) was applied. The number of revolutions at the time of application was 1500 rpm, and application was conducted for 30 seconds.

Thus, a resist layer was formed on the substrate with an adhesive auxiliary layer according to this example, thereby producing a substrate for copy mold production.

### Example 2

In example 1, an adhesive auxiliary agent that includes a modified silane group and a mercapto group was used. Instead, in example 2, an adhesive auxiliary agent (Z6030 made by Dow Corning) that includes a modified silane group and a methacryl group was used. Other conditions were the same as those of example 1. Thus, a resist layer was formed on the substrate with an adhesive auxiliary layer, thereby producing a substrate for copy mold production.

### Example 3

In example 3, only chromium nitride was used for the hard mask layer 7 and other conditions were the same as those of example 1. Thus, a resist layer was formed on the substrate with an adhesive auxiliary layer, thereby producing a substrate for copy mold production. At that time, the chromium nitride layer was 5 nm thick.

### Comparative examples 1 to 3

For the comparison with the above-mentioned examples, in comparative example 1, a compound (HMDS) (made by AZ Electronic Materials) that includes only a modified silane group was used as an adhesive auxiliary agent.

In comparative example 2, a compound that includes an acrylic group was used as an adhesive auxiliary agent.

In comparative example 3, no adhesive auxiliary agent was used.

Other than the above, conditions were the same as those of the examples. Thus, a resist layer was formed on the substrate with an adhesive auxiliary layer, thereby producing a substrate for copy mold production.

<Evaluation>

A variety of evaluations were conducted with regard to the substrates for copy mold production wherein a resist layer was formed on the substrate with an adhesive auxiliary layer obtained by examples and comparative examples.

1) Adhesive Strength

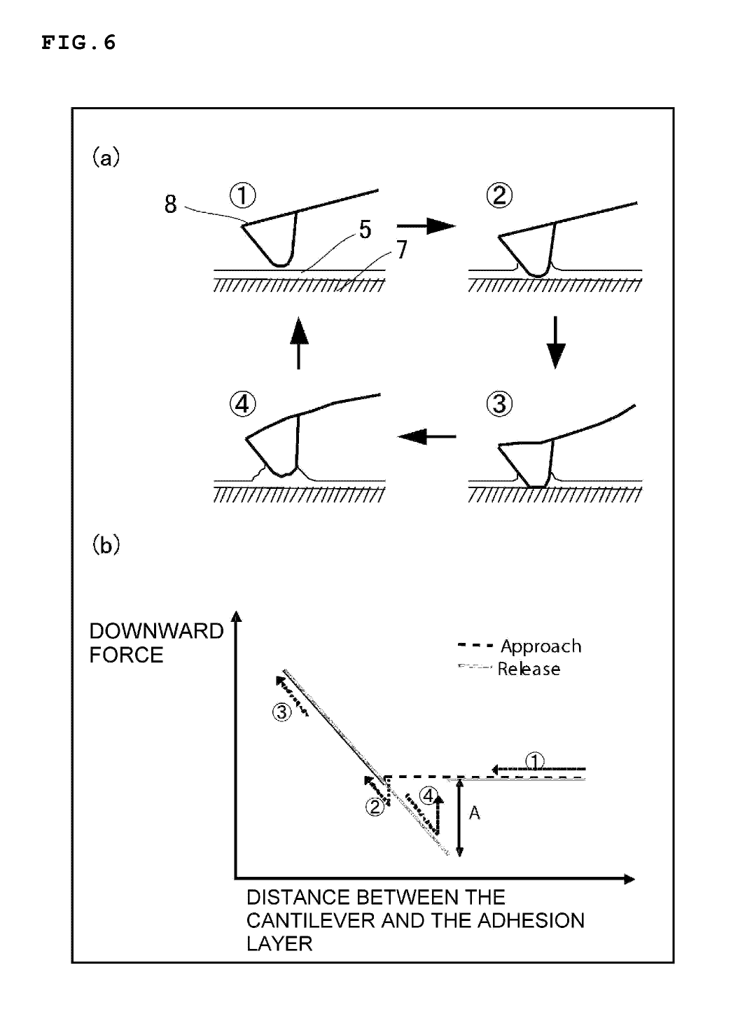

FIG. 6 shows a specific example of a method for evaluating the adhesive strength. As shown in FIG. 6(a), a cantilever 8 was come in contact with an adhesive auxiliary layer 5 formed on a hard mask layer 7, and then the cantilever 8 was pulled up. FIG. 6(b) shows the relationship between the force (a downward force is plotted on the y axis) applied to the cantilever 8 at that time and the distance between the tip of the cantilever 8 and the adhesive auxiliary layer 5.

As shown in FIG. 6(a)(1), before the evaluation test, the cantilever 8 has not come in contact with the adhesive auxiliary layer 5. Therefore, a force applied to the cantilever 8 is constant (FIG. 6(b)(1)).

After that, as shown in FIG. 6(a)(2), the cantilever 8 comes in contact with the adhesive auxiliary layer 5. Until the cantilever 8 comes in contact with the hard mask layer 7 (before reaching the state in FIG. 6(a)(3)) a force applied to the cantilever 8 increases (FIG. 6(b)(2) and (3)).

Next, to pull the cantilever 8 away, as shown in FIG. 6(a)(4), an upward force is applied to the cantilever 8 (FIG. 6(b)(4)).

To return to the state where the cantilever 8 does not come in contact with the adhesive auxiliary layer 5 (the state in FIG. 6(a)(1)), an extra upward force becomes necessary when compared with the force applied to the cantilever 8 in the state in FIG. 6(a)(1) to (3) (the arrow A on FIG. 6(b)).

In this example, the value of this force is considered to indicate adhesive strength of the adhesive auxiliary layer 5. Herein, the force applied to the cantilever 8 was examined by use of an atomic force microscope (AFM).

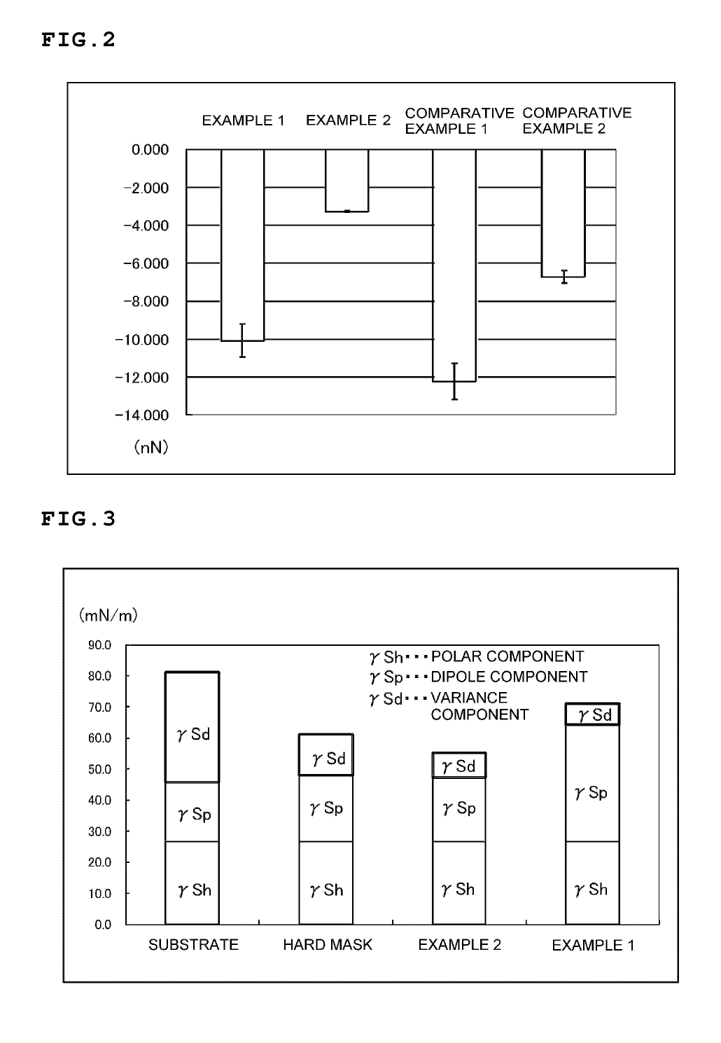

When looking at FIG. 2 that shows the results of adhesive strength of the substrate with an adhesive auxiliary layer obtained by the examples and comparative examples, it was found that example 1 (mercapto group) has adhesive strength even equal to comparative example 1. Although not shown in FIG. 2, the result of example 3 was also the same as that of example 1. Also in example 2 (methacryl group), it was found that adhesive strength is sufficient for practical use.

2) Surface Free Energy

Next, surface free energy was evaluated by a contact-angle measuring technique. The results are shown in FIG. 3. As reference, surface free energy of the substrate 1 and the hard mask layer 7 was also evaluated.

As shown in FIG. 3, with respect to example 1 (mercapto group), it was found that high surface free energy was obtained and good wettability was provided for an organic compound. Although not shown in FIG. 3, the result of example 3 was also the same as that of example 1. Also in example 2 (methacryl group), it was found that good wettability was provided for an organic compound.

3) Surface Roughness

Next, evaluation was conducted for surface roughness of the substrates for copy mold production wherein a resist layer 4 was formed on a substrate with an adhesive auxiliary layer according to examples and comparative examples.

The reason why surface roughness was evaluated herein is as follows:

When a light curable resin is used as a resist layer 4, when the light curable resin is hardened by the irradiation of light, the resist layer generally contracts.

If adhesive strength between the resist layer 4 and the adhesive auxiliary layer 5 is insufficient, the resist layer 4 hardened by the irradiation of light is removed from the adhesive auxiliary layer 5.

As a result, roughness occurs on the surface of the resist layer 4.

That is, the inventors of the present invention considered that surface roughness could be one index that indicates adhesive strength.

FIG. 4 shows the results of the surface roughness, observed with the AFM, of the substrates with an adhesive auxiliary layer obtained by the examples and comparative examples. FIG. 5 shows the numeric results. As shown in FIG. 4(a) of example 1 and FIG. 4(b) of example 2, the surfaces in the examples were all smooth. Although not shown in FIG. 4, the result of example 3 was also the same as that of example 1.

Of all examples, specifically in example 2 (methacryl group) shown in FIG. 4(b), surface roughness was significantly small; a good surface was obtained.

On the other hand, in comparative examples 1 to 3, as shown in corresponding FIG. 4(c) to (e), surfaces are rough. Therefore, when considering the comparatively poor adhesive strength and rough surfaces, it seems to be difficult to form an accurate pattern.

### Example 4

After a substrate for copy mold production was made by forming a resist layer 4 on a substrate with an adhesive auxiliary layer that includes a modified silane group and a mercapto group in example 1, the substrate with an adhesive auxiliary layer was baked at 80° C. for 20 minutes before the exposure process.

Subsequently, a pattern was transferred onto the substrate by using an optical imprinting apparatus (irradiation for 120 seconds by the UV exposure apparatus made by Meisho) at a pressure of 2.2 MPa with 120-second ultraviolet irradiation by using an original mold 30 on which a projection and recess pattern of the 120-nm pitch discreet track recording patterned medium has been formed. The original mold 30 was beforehand coated with a mold release agent DDOH (made by MORESCO) to form a demolding layer.

After the pattern was transferred onto the resist layer 4 as stated above, observation by an optical microscope was conducted, and the percentage of the area of the portion of the resist layer 4 from which removal had occurred was obtained. As a result, the percentage of the area was less than 1%; it was found that good adhesive strength was obtained.

### REFERENCE SIGNS LIST

1 Substrate
2 Conductive layer
3 Chromium nitride layer
4 Resist layer
5 Adhesive auxiliary layer
7 Hard mask layer
8 Cantilever
10 Mold with the remaining hard mask layer
20 Copy mold
30 Original mold

1. A substrate with an adhesive auxiliary layer having an organic compound layer provided on the substrate, with an adhesive auxiliary layer to be interposed between the substrate and the organic compound layer,
wherein one molecule of a compound contained in the adhesive auxiliary layer includes an adsorption functional group and an adhesion promoting functional group,
the adsorption functional group is composed of a modified silane group which is mainly bonded to the substrate, and
the adhesion promoting functional group promotes and increases adhesion mainly to the organic compound layer.

2. The substrate with an adhesive auxiliary layer according to claim 1, wherein
the organic compound layer is a resist layer, and
a photoradical reaction is induced between the adhesion promoting functional group and the resist layer.

3. The substrate with an adhesive auxiliary layer according to claim 1, wherein the adhesion promoting functional group is a functional group in which when a chemical agent that is a source of the organic compound layer is applied to the adhesive auxiliary layer, a contact angle between the adhesive auxiliary layer and the chemical agent is 30 degrees or less.

4. The substrate with an adhesive auxiliary layer according to claim 1, wherein the adhesion promoting functional group is a mercapto group.

5. The substrate with an adhesive auxiliary layer according to claim 1, wherein the adhesion promoting functional group is a methacryl group or an epoxy group.

6. The substrate with an adhesive auxiliary layer according to claim 1, wherein the adhesion promoting functional group is provided on at least one terminal of a molecular chain.

7. The substrate with an adhesive auxiliary layer according to claim 1, wherein the modified silane group is provided on at least one terminal of a molecular chain.

8. The substrate with an adhesive auxiliary layer according to claim 1, wherein the modified silane group is an alkoxysilane group.

9. The substrate with an adhesive auxiliary layer according to claim 8, wherein the alkoxysilane group is a trimethoxy silane group.

10. The substrate with an adhesive auxiliary layer according to claim 1, wherein the organic compound layer is a resist layer, and the resist layer is composed of light curable resin.

11. The substrate with an adhesive auxiliary layer according to claim 1, wherein the organic compound layer is a resist layer, and the resist layer is composed of a resist for electron-beam lithography exposure having no substantial sensitivity to an ultraviolet band.

12. A substrate with an adhesive auxiliary layer having an organic compound layer provided on a substrate, with an adhesive auxiliary layer to be interposed between the substrate and the organic compound layer,
wherein
a trimethoxy silane group is provided on one terminal of a molecular chain in one molecule of a compound contained in the adhesive auxiliary layer, and
a mercapto group, a methacryl group, or an epoxy group is provided on the other terminal.

13. A manufacturing method of a mold wherein an another copy mold is manufactured from an imprint mold provided with a projection and recess pattern that corresponds to a designed pattern, the method comprising:
forming a hard mask layer on a substrate for producing the another copy mold, an adhesive auxiliary layer on the hard mask layer, and an imprint resist layer for pattern formation (hereafter, also referred to as a resist layer) on the adhesive auxiliary layer;
transferring a pattern provided on the mold onto the resist layer by imprinting; and
separating the mold from the resist layer and then applying etching to the hard mask layer by using the resist layer with a transferred designed pattern as a mask,
wherein
an adsorption functional group and an adhesion promoting functional group are included in one molecule of a compound contained in the adhesive auxiliary layer,
the adsorption functional group made of a modified silane group is mainly bonded to the substrate by baking the adhesive auxiliary layer during formation of this layer, and
the adhesion promoting functional group promotes and increases adhesion mainly to the resist layer.

14. The manufacturing method of a mold according to claim 13, wherein
in the step of transferring a projection and recess pattern provided on the mold onto the resist layer by an optical imprint method,
a photoradical reaction is induced between the resist layer and the adhesion promoting functional group by an irradiation light used in the optical imprint method.

15. A manufacturing method of a master mold for imprint, comprising:
forming a hard mask layer on a substrate, an adhesive auxiliary layer on the hard mask layer, and an electron-beam lithography exposure resist layer for pattern formation (also referred to as an electron-beam resist layer) on the adhesive auxiliary layer;
irradiating the substrate having the hard mask layer, the adhesive auxiliary layer, and the electron-beam resist layer sequentially formed thereon, with a light by using a light irradiation apparatus;
drawing and exposing a designed pattern on the electron-beam resist layer by an electron-beam lithography (exposure) system, and the electron-beam resist layer is then developed, to thereby form a predetermined resist pattern; and
applying etching to the hard mask layer by using the electron-beam resist layer with a designed pattern formed thereon (resist pattern) as a mask,
wherein
an adsorption functional group and an adhesion promoting functional group are included in one molecule of a compound contained in the adhesive auxiliary layer,
the adsorption functional group made of a modified silane group is mainly bonded to the substrate by baking the adhesive auxiliary layer during formation of this layer, and
the adhesion promoting functional group promotes and increases adhesion mainly to the resist layer.

16. The manufacturing method of a master mold according to claim 15, wherein a photoradical reaction is induced between the electron beam resist layer and the adhesion promoting functional group by the light irradiation at least before developing of the electron-beam resist layer.
